(19) United States
(12) Patent Application Publication
(10) Pub. No.: US 2011/0260176 A1
(43) Pub. Date: Oct. 27, 2011

(54) LIGHT-EMITTING SENSOR DEVICE AND METHOD FOR MANUFACTURING THE SAME

(75) Inventors: Atsushi Onoe, Saitama (JP); Yoshinori Kimura, Hanno (JP)

(73) Assignee: PIONEER CORPORATION, Kawasaki-shi, Kanagawa (JP)

(21) Appl. No.: 12/991,964

(22) PCT Filed: May 12, 2008
(86) PCT No.: PCT/JP2008/058694

§ 371 Date: Dec. 3, 2010

(51) Int. Cl. H01L 33/00

(52) U.S. Cl. 257/79; 438/33; 257/E33.001

(57) ABSTRACT

A light-emitting sensor device is provided with: a substrate (110); an irradiating part (120), disposed on the substrate, for applying light to a specimen; a light receiving part (150), disposed on the substrate, for detecting light from the specimen caused by the applied light; a front plate (190) disposed to face the substrate, on a front surface side of the substrate in which the irradiating part is disposed; and an adhesive part (180) which is formed to surround each of the irradiating part and the light receiving part viewed in a two-dimensional manner on the substrate, which includes a light shielding adhesive, and which bonds the substrate and the front plate to each other. By this, the light-emitting sensor device is suitable for mass production, and it is possible to detect a predetermined type of information, such as a blood flow velocity, on a specimen, highly accurately.

### TECHNICAL FIELD

The present invention relates to a light-emitting sensor device capable of measuring a blood flow velocity or the like, and a method of making the same.

### BACKGROUND ART

As this type of light-emitting sensor device, there is a device for applying light such as laser light to a living body and for calculating the blood flow velocity of the living body from a change in wavelength by Doppler shift in its reflection or scattering (e.g. refer to patent documents 1 and 2). In this type of light-emitting sensor device, typically, miniaturization is expected by providing a light source such as a semiconductor laser for applying light to a living body and a light detector such as a photodiode for detecting light from the living body to be close to each other, in an enclosure or housing. Moreover, in most cases, such a light-emitting sensor device has a light shielding structure for preventing light which should not be detected, such as light directly going to the light detector without being applied to the living body, out of light from the light source from being detected by the light detector. Such a light shielding structure is realized in a patent document 1 by providing a light shielding plate between the semiconductor laser and the photodiode in the enclosure. In a patent document 2, the light shielding structure is realized by separately disposing the semiconductor laser and the photodiode in each of two concave portions formed by performing an anisotropy process on a silicon substrate and forming a light shielding film on the inner surface of the concave portion.
Patent document 1: Japanese Patent Application Laid Open No. 2004-357784
Patent document 2: Japanese Patent Application Laid Open No. 2004-229920

### DISCLOSURE OF INVENTION

### Subject to be Solved by the Invention

However, for example, according to the technologies disclosed in the patent documents 1 and 2, the light-emitting sensor device including the aforementioned light shielding structure has a complicated structure, so that there is such a technical problem that processes requiring a lot of time increase and the number of the processes increases in a manufacturing process. Thus, a yield in the manufacturing process likely decreases, resulting in an increase in manufacturing cost of the device.

For example, in the technology disclosed in the patent document 1, it is necessary to incorporate relatively many parts in the enclosure including the aforementioned light shielding plate, a reflection plate for guiding the light from the semiconductor laser to the living body side, a reflective plate for guiding the light from the living body to the photodiode side, or the like in addition to the semiconductor laser and the photodiode. Thus, the number of processes likely increases, and it likely requires a lot of time for the positioning of the parts. Moreover, in the technology disclosed in the patent document 2, for example, a small sensor device which is several millimeters×several millimeters in size can be realized; however, it likely takes a lot of time to perform the anisotropy etching process for forming the concave portion on the silicon substrate, and the yield likely decreases due to variations in the manufacture caused by the anisotropy etching process.

In view of the aforementioned problems, it is therefore an object of the present invention to provide a small light-emitting sensor device, which is suitable for mass production and which can detect a predetermined type of information such as a blood flow velocity on a specimen, highly accurately, and its manufacturing method.

### Means for Solving the Subject

The above object of the present invention can be achieved by a light-emitting sensor device provided with: a substrate; an irradiating part, disposed on the substrate, for applying light to a specimen; a light receiving part, disposed on the substrate, for detecting light from the specimen caused by the applied light; a front plate disposed to face the substrate, on a front surface side of the substrate in which the irradiating part is disposed; and an adhesive part which is formed to surround each of the irradiating part and the light receiving part viewed in a two-dimensional manner on the substrate, which includes a light shielding adhesive, and which bonds the substrate and the front plate to each other.

According to the light-emitting sensor device of the present invention, in its detection, the light such as laser light is applied to the specimen, which is one portion of a living body, by the irradiating part including e.g. a semiconductor laser. The light from the specimen caused by the light applied to the specimen in this manner is detected by the light receiving part including e.g. a light receiving element. Here, the “light from the specimen caused by the light applied to the specimen” means light caused by the light applied to the specimen, such as lights reflected, scattered, diffracted, refracted, transmitted through, Doppler-shifted in the specimen and interfering light by the above lights. On the basis of the light detected by the light receiving part, it is possible to obtain predetermined information such as a blood flow velocity associated with the specimen.

Incidentally, the front plate is made of a light shielding plate-like member where an exit aperture for transmitting the light emitted from the irradiating part and an entrance aperture for transmitting the light from the specimen are formed.

In the present invention, in particular, the substrate on which the irradiating part and the light receiving part are formed and the front plate are bonded to each other by the adhesive part including the light shielding adhesive. Moreover, the adhesive part is formed to surround each of the irradiating part and the light receiving part viewed in a two-dimensional manner on the substrate.

Thus, the adhesive part can surely bond the substrate and the front plate. Moreover, by virtue of the adhesive part, it is possible to prevent unnecessary light from the surroundings of the light-emitting sensor device from entering the irradiating part and the light receiving part. In addition, by virtue of the adhesive part, it is possible to block the light directly going from the irradiating part to the light receiving part, out of the light emitted from the irradiating part (i.e. the light which is emitted from the irradiating part and which goes to the light receiving part without being applied to the specimen). Therefore, it is possible to prevent that the light detected by the light receiving part changes due to the unnecessary light from the surroundings of the light-emitting sensor device and the light directly going from the irradiating part to the light receiving part. As a result, it is possible to detect the predetermined type of information, such as a blood flow velocity, on the specimen, more highly accurately. Incidentally, the adhesive part can also function as a spacer for defying a gap between the substrate and the front plate.

Moreover, particularly in the present invention, as described above, the substrate and the front plate are bonded to each other by the adhesive part. In other words, the light-emitting sensor device of the present invention has a laminated structure in which the substrate on which the irradiating part and the light receiving part are formed and the front plate are laminated via the adhesive part. Thus, in manufacturing the light-emitting sensor device of the present invention, for example, after the irradiating part and the light receiving part are formed on a flat substrate surface on the substrate, the front plate may be bonded to the substrate by the adhesive part.

In other words, the light-emitting sensor device of the present invention has a relatively simple structure, which is a laminated structure, in which the substrate and the front plate are laminated by the adhesive part, so that it is possible to simplify or reduce each process in a manufacturing process. Thus, it is possible to increase the yield and to reduce the manufacturing cost as well.

As explained above, according to the light-emitting sensor device of the present invention, it is possible to detect the predetermined type of information, such as a blood flow velocity, on the specimen, highly accurately. Moreover, it is possible to increase the yield and to reduce the manufacturing cost, and it is suitable for mass production.

In one aspect of the light-emitting sensor device of the present invention, the adhesive part is made only of the light shielding adhesive.

According to this aspect, the structure of the adhesive part is relatively simple, so that it is possible to simplify, for example, a process of forming the adhesive part. Thus, it is possible to further increase the yield and to further reduce the manufacturing cost as well.

In another aspect of the light-emitting sensor device of the present invention, the adhesive part includes a frame member which has higher strength than the light shielding adhesive and which surrounds each of the irradiating part and said light receiving part viewed in a two-dimensional manner on the substrate.

According to this aspect, it is possible to increase the strength of the adhesive part. Thus, for example, the function as the spacer of the adhesive part can be increased. Therefore, it is possible to limit or control a change in the gap between the substrate and the front plate.

In another aspect of the light-emitting sensor device of the present invention, the light shielding adhesive is an acrylic, epoxy, polyimide or silicon type adhesive in which light shielding particles are dispersed inside.

According to this aspect, the adhesive part includes the acrylic, epoxy, polyimide or silicon type adhesive in which the light shielding particles are dispersed inside, as the light shielding adhesive. Thus, the adhesive part can surely bond the substrate and the front plate. Moreover, by virtue of the adhesive part, it is possible to prevent the unnecessary light from the surroundings of the light-emitting sensor device from entering the irradiating part and the light receiving part. In addition, by virtue of the adhesive part, it is possible to surely block the light directly going from the irradiating part to the light receiving part, out of the light emitted from the irradiating part. Incidentally, as the light shielding particles, conducting particles, such as carbon black, aluminum and silver, and black pigments can be listed.

In another aspect of the light-emitting sensor device of the present invention, the irradiating part and the light receiving part are integrated on the substrate.

According to this aspect, the irradiating part and the light receiving part are integrated, so that the layout area for each part is reduced, which further allows miniaturization. Due to the miniaturization, it is possible to extend the use of the light-emitting sensor device, such as making it not of a stationary type but a mobile type.

In another aspect of the light-emitting sensor device of the present invention, it is further provided with a calculating part for calculating a blood flow velocity associated with the specimen, on the basis of the detected light.

According to this aspect, by using that the penetration force of light to a living body depends on wavelength, it is possible to measure the blood flow velocity of each of blood vessels which have different depth from the skin surface. Specifically, by applying light to the surface of a living body, the light penetrating into the body is reflected or scattered by red blood cells flowing in the blood vessel, and its wavelength changes due to the Doppler-shift according to the transfer rate of the red blood cells. On the other hand, as for the light reflected or scattered by skin tissue which can be considered immovable with respect to the red blood cells, the light reaches to the light receiving part without any change in the wavelength. By those lights interfering with each other, an optical beat signal corresponding to the Doppler shift amount is detected on the light receiving part. The calculating part performs an arithmetic process, such as frequency analysis, on the optical beat signal, thereby calculating the velocity of the blood flowing in the blood vessel.

In another aspect of the light-emitting sensor device of the present invention, the irradiating part has a semiconductor laser for generating laser light as the light.

According to this aspect, the laser light can be applied by applying a voltage to the semiconductor of the irradiating part such that an electric current flows with a higher value than a laser oscillation threshold value. The laser light has such a character that it has a different penetration force to a living body or the like depending on a difference in wavelength. By using such a character, it is possible to perform the measurement in different depth of the specimen.

The above object of the present invention can be also achieved by a first method of manufacturing a light-emitting sensor device provided with: a substrate; an irradiating part, disposed on the substrate, for applying light to a specimen; a light receiving part, disposed on the substrate, for detecting light from the specimen caused by the applied light; a front plate disposed to face the substrate, on a front surface side of the substrate in which the irradiating part is disposed; and an adhesive part which is formed to surround each of the irradiating part and the light receiving part viewed in a two-dimensional manner on the substrate, which includes a light shielding adhesive, and which bonds the substrate and the front plate to each other, the method provided with: a forming process of forming the irradiating part and the light receiving part on a first large substrate including a plurality of substrates; an applying process of applying the light shielding adhesive so as to surround each of the irradiating part and the light receiving part on the first large substrate; an adhering process of disposing a second large substrate including a plurality of front plates so as to face the first large substrate to which the light shielding adhesive is applied and of bonding the first and second large substrates to each other by the light shielding adhesive; and a cutting process of cutting the first and second large substrates bonded to each other, along circumference of the substrate.

According to the first method of manufacturing a light-emitting sensor device of the present invention, the aforementioned light-emitting sensor device of the present invention can be manufactured. Here, in particular, the light shielding adhesive is applied, for example, by using a dispenser (an apparatus for discharging a certain amount of liquid) so as to surround each of the irradiating part and the light receiving part on the first large substrate. Moreover, after the first and second large substrates are bonded to each other, the first and second large substrates are cut along the circumference of the substrate. Thus, it is possible to manufacture a plurality of light-emitting sensor devices, simultaneously.

The above object of the present invention can be also achieved by a second method of manufacturing a light-emitting sensor device provided with: a substrate; an irradiating part, disposed on the substrate, for applying light to a specimen; a light receiving part, disposed on the substrate, for detecting light from the specimen caused by the applied light; a front plate disposed to face the substrate, on a front surface side of the substrate in which the irradiating part is disposed; and an adhesive part which is formed to surround each of the irradiating part and the light receiving part viewed in a two-dimensional manner on the substrate, which includes a light shielding adhesive, and which bonds the substrate and the front plate to each other, the method provided with: a forming process of forming the irradiating part and the light receiving part on a first large substrate including a plurality of substrates; a disposing process of disposing an adhesive sheet on the first large substrate, the adhesive sheet being formed to surround each of the irradiating part and the light receiving part on the first large substrate, the adhesive sheet being made of the light shielding adhesive; an adhering process of disposing a second large substrate including a plurality of front plates so as to face the first large substrate on which the adhesive sheet is disposed and of bonding the first and second large substrates to each other by the adhesive sheet; and a cutting process of cutting the first and second large substrates bonded to each other, along circumference of the substrate.

According to the second method of manufacturing a light-emitting sensor device of the present invention, the aforementioned light-emitting sensor device of the present invention can be manufactured. Here, in particular, the first and second large substrates to each other by the adhesive sheet which is formed to surround each of the irradiating part and the light receiving part on the first large substrate and which is made of the light shielding adhesive. Thus, it is possible to easily form the adhesive part which is made only of the light shielding adhesive. Moreover, after the first and second large substrates are bonded to each other, the first and second large substrates are cut along the circumference of the substrate. Thus, it is possible to manufacture a plurality of light-emitting sensor devices, simultaneously.

The above object of the present invention can be also achieved by a third method of manufacturing a light-emitting sensor device provided with: a substrate; an irradiating part, disposed on the substrate, for applying light to a specimen; a light receiving part, disposed on the substrate, for detecting light from the specimen caused by the applied light; a front plate disposed to face the substrate, on a front surface side of the substrate in which the irradiating part is disposed; and an adhesive part which is formed to surround each of the irradiating part and the light receiving part viewed in a two-dimensional manner on the substrate, which includes a light shielding adhesive, and which bonds the substrate and the front plate to each other, the method provided with: a forming process of forming the irradiating part and the light receiving part on a first large substrate including a plurality of substrates; an applying process of applying the light shielding adhesive to a large frame member by dipping, the large frame member having higher strength than the light shielding adhesive, the large frame member being formed to surround each of the irradiating part and the light receiving part viewed in a two-dimensional manner on the first large substrate; an adhering process of disposing a second large substrate including a plurality of front plates so as to face the first large substrate via the large frame member to which the light shielding adhesive is applied and of bonding the first and second large substrates to each other by the light shielding adhesive; and a cutting process of cutting the first and second large substrates bonded to each other, along circumference of the substrate.

According to the third method of manufacturing a light-emitting sensor device of the present invention, the aforementioned light-emitting sensor device of the present invention can be manufactured. Here, in particular, the light shielding adhesive is applied to the large frame member by dipping. Thus, it is possible to easily form the adhesive part which is made of the frame member and the light shielding adhesive. Moreover, after the first and second large substrates are bonded to each other, the first and second large substrates are cut along the circumference of the substrate. Thus, it is possible to manufacture a plurality of light-emitting sensor devices, simultaneously.

The above object of the present invention can be also achieved by a fourth method of manufacturing a light-emitting sensor device provided with: a substrate; an irradiating part, disposed on the substrate, for applying light to a specimen; a light receiving part, disposed on the substrate, for detecting light from the specimen caused by the applied light; a front plate disposed to face the substrate, on a front surface side of the substrate in which the irradiating part is disposed; and an adhesive part which is formed to surround each of the irradiating part and the light receiving part viewed in a two-dimensional manner on the substrate, which includes a light shielding adhesive, and which bonds the substrate and the front plate to each other, the method provided with: a forming process of forming the irradiating part and the light receiving part on a first large substrate including a plurality of substrates; an applying process of applying the light shielding adhesive to a first surface opposed to the first large substrate and a second surface opposite to the first surface, in a large frame member which has higher strength than the light shielding adhesive and which is formed to surround each of the irradiating part and the light receiving part viewed in a two-dimensional manner on the first large substrate; an adhering process of disposing a second large substrate including a plurality of front plates so as to face the first large substrate via the large frame member to which the light shielding adhesive is applied and of bonding the first and second large substrates to each other by the light shielding adhesive via the large frame member; and a cutting process of cutting the first and second large substrates bonded to each other, along circumference of the substrate.

According to the fourth method of manufacturing a light-emitting sensor device of the present invention, the aforementioned light-emitting sensor device of the present invention can be manufactured. Here, in particular, the light shielding adhesive is applied to the first surface (i.e. a lower surface) opposed to the first large substrate and the second surface (i.e. an upper surface) opposite to the first surface, in the large frame member, by using a roller or the like. Thus, it is possible to easily form the adhesive part having the structure that the upper surface and the lower surface of the frame member are covered with the light shielding adhesive. Moreover, after the first and second large substrates are bonded to each other, the first and second large substrates are cut along the circumference of the substrate. Thus, it is possible to manufacture a plurality of light-emitting sensor devices, simultaneously.

The operation and other advantages of the present invention will become more apparent from the embodiments explained below.

As explained in detail above, according to the light-emitting sensor device of the present invention, it is provided with the substrate, the irradiating part, the light receiving part, the front plate, and the adhesive part. Thus, it is possible to detect the predetermined type of information, such as a blood flow velocity, on the specimen, highly accurately. Moreover, it is possible to increase the yield and to reduce the manufacturing cost, and it is suitable for mass production. Moreover, according to the first to fourth methods of manufacturing a light-emitting sensor device of the present invention, it is possible to manufacture the light-emitting sensor device of the present invention described above.

### BRIEF DESCRIPTION OF DRAWINGS

FIG. 1 is a plan view showing the structure of a sensor part of a blood flow sensor device in a first embodiment.

FIG. 2 is an A-A′ cross sectional view in FIG. 1.

FIG. 3 is a plan view showing the structure of a front plate of the blood flow sensor device in the first embodiment.

FIG. 4 is a cross sectional view having the same concept as in FIG. 2 in a first modified example.

FIG. 5 is a cross sectional view having the same concept as in FIG. 2 in a second modified example.

FIG. 6 is a block diagram showing the structure of the blood flow sensor device in the first embodiment.

FIG. 7 is a conceptual view showing one example of how to use the blood flow sensor device in the first embodiment.

FIG. 8 is a plan view showing the structure of a sensor part of a blood flow sensor device in a second embodiment.

FIG. 9 is a B-B′ cross sectional view in FIG. 8.

FIG. 10 is a cross sectional view having the same concept as in FIG. 2 in a third embodiment.

FIG. 11 is a flowchart showing a flow of a method of manufacturing the light-emitting sensor device in a first embodiment.

FIG. 12 is a plan view showing a sensor part substrate wafer after a laser diode, a photodiode and the like are formed.

FIG. 13 is a conceptual view showing a process of applying an adhesive in the method of manufacturing the light-emitting sensor device in the first embodiment.

FIG. 14 is a flowchart showing a flow of a method of manufacturing the light-emitting sensor device in a second embodiment.

FIG. 15 is a conceptual view showing a process of setting an adhesive seal in the method of manufacturing the light-emitting sensor device in the second embodiment.

FIG. 16 is a flowchart showing a flow of a method of manufacturing the light-emitting sensor device in a third embodiment.

FIG. 17 is a perspective view showing a large frame member in the method of manufacturing the light-emitting sensor device in the third embodiment.

FIG. 18 is a cross sectional view showing that a sensor part substrate wafer and a front plate array substrate are disposed to face each other via the large frame member after a light shielding adhesive is applied by dipping, in the method of manufacturing the light-emitting sensor device in the third embodiment.

FIG. 19 is a flowchart showing a flow of a method of manufacturing the light-emitting sensor device in a fourth embodiment.

FIG. 20 is a cross sectional view showing that the sensor part substrate wafer and the front plate array substrate are disposed to face each other via the large frame member to which the light shielding adhesive is applied, in the method of manufacturing the light-emitting sensor device in the fourth embodiment.

### DESCRIPTION OF REFERENCE CODES

100, 102, 103 sensor part
110 sensor part substrate
120 laser diode
130 electrode
150 laser diode drive circuit
160 photodiode
170 photodiode amplifier
180, 200, 201 adhesive part
189 adhesive sheet
190 front plate
210 adhesive portion
220 frame member
310 A/D converter
320 blood flow velocity DSP
510 sensor part substrate wafer
601 large frame member
710 front plate array substrate
910 dispenser

### BEST MODE FOR CARRYING OUT THE INVENTION

Hereinafter, embodiments of the present invention will be explained with reference to the drawings. Incidentally, the embodiments below exemplify a blood flow sensor device, which is one example of the light-emitting sensor device of the present invention.

### <First Embodiment of Light-Emitting Sensor Device>

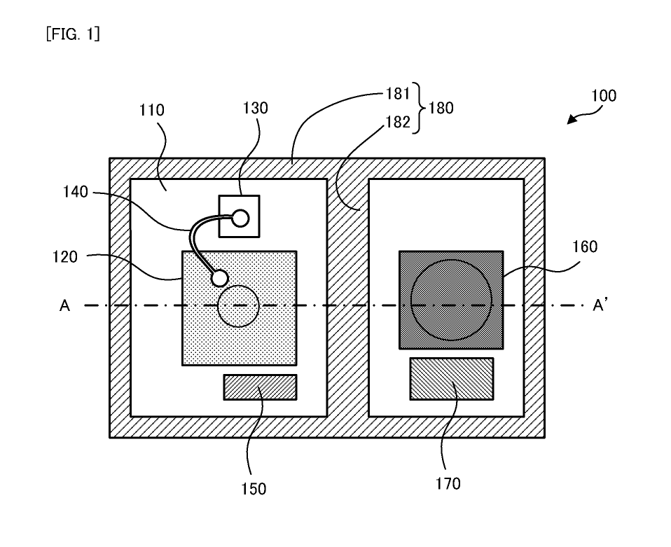

A blood flow sensor device in a first embodiment will be explained with reference to FIG. 1 to FIG. 7.

Firstly, the structure of a sensor part of the blood flow sensor device in the first embodiment will be explained with reference to FIG. 1 to FIG. 3.

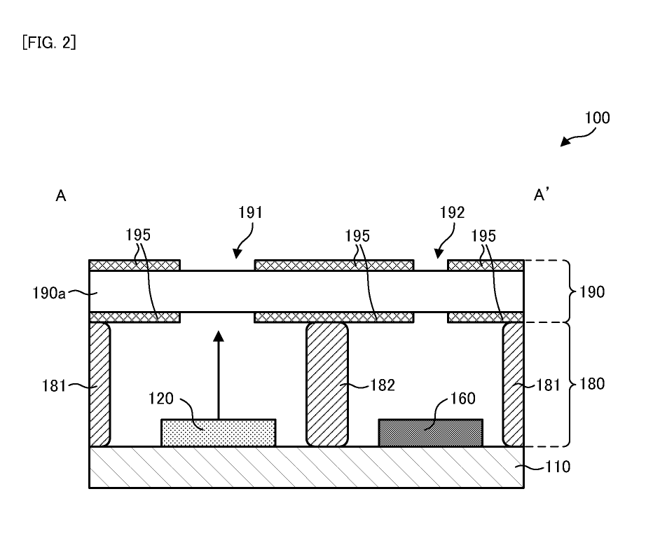

FIG. 1 is a plan view showing the structure of the sensor part of the blood flow sensor device in the first embodiment. FIG. 2 is an A-A′ cross sectional view in FIG. 1. Incidentally, in FIG. 1, for convenience of explanation, the illustration of a front plate 190 shown in FIG. 2 is omitted.

As shown in FIG. 1 and FIG. 2, a sensor part 100 of the blood flow sensor device in the first embodiment is provided with a sensor part substrate 110, a laser diode 120, an electrode 130, a wire line 140, a laser diode drive circuit 150, a photodiode 160, a photodiode amplifier 170, an adhesive part 180, and a front plate 190.

The sensor part substrate 110 is made of a semiconductor substrate, such as a silicon substrate. On the sensor part substrate 110, the laser diode 120, the laser diode drive circuit 150, the photodiode 160, and the photodiode amplifier 170 are integrated and disposed.

The laser diode 120 is one example of the “irradiating part” of the present invention, and it is a semiconductor laser for emitting laser light. The laser diode 120 is electrically connected to the electrode 130 through the wire line 140. The electrode 130 is electrically connected to an electrode pad (not illustrated) disposed on the bottom of the sensor part substrate 100 by wiring (not illustrate) which penetrates the sensor part substrate 110. Moreover, the other electrode (not illustrate) formed on the bottom surface of the laser diode 120 is electrically connected to an electrode pad (not illustrated) disposed on the bottom of the sensor part substrate 100 by wiring (not illustrate) on the sensor substrate or wiring (not illustrate) which penetrates the sensor part substrate 110, and it can drive the laser diode 120 by current injection from the exterior of the sensor part 100.

The laser diode drive circuit 150 is a circuit for controlling the drive of the laser diode 120, and it controls the amount of an electric current injected to the laser diode 120.

The photodiode 160 is one example of the “light receiving part” of the present invention, and it functions as a light detector for detecting the light reflected or scattered from a specimen. Specifically, the photodiode 160 can obtain information about light intensity by converting the light to an electric signal. The photodiode 160 is disposed in parallel with the laser diode 120 on the sensor part substrate 110. The light received on the photodiode 160 is converted to the electric signal and is inputted to the photodiode amplifier 170 via a wire line (not illustrated) and an electrode (not illustrated) formed on the bottom surface of the photodiode 160 or the like.

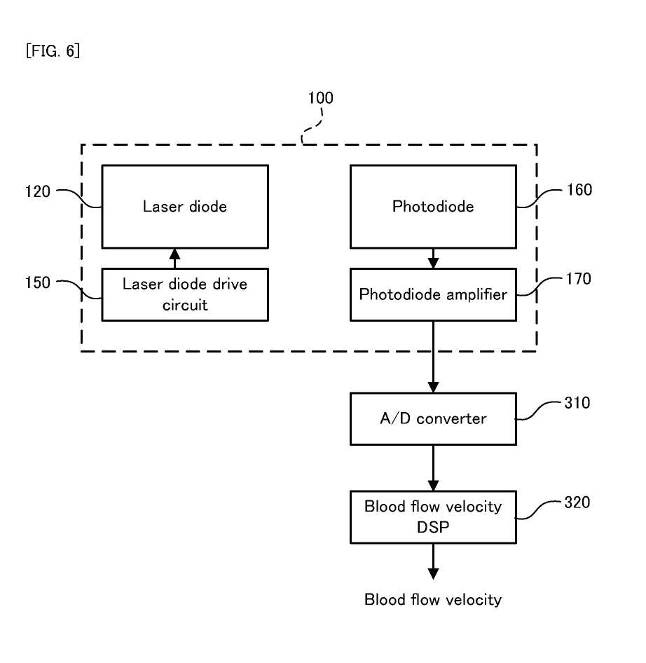

The photodiode amplifier 170 is an amplifier circuit for amplifying the electric signal obtained by the photodiode 160. The photodiode amplifier 170 is electrically connected to the electric pad (not illustrated) disposed on the bottom of the sensor part substrate 100 by the wiring (not illustrate) which penetrates the sensor part substrate 110, and it can output the amplified electric signal to the exterior. The photodiode amplifier 170 is electrically connected to an A/D (Analog to Digital) converter 310 (refer to FIG. 6 described later) disposed in the exterior of the sensor part 100.

The adhesive part 180 is made of a light shielding adhesive, and it bonds the sensor part substrate 110 and the front plate 190. The light shielding adhesive may be an acrylic, epoxy, polyimide or silicon type adhesive in which conducting particles, such as carbon black, aluminum and silver, are dispersed inside, or an acrylic, epoxy, polyimide or silicon type adhesive in which pigments, such as black pigments, are dispersed inside. The adhesive 180 is formed to surround each of the laser diode 120 and the photo diode 160, viewed in a two-dimensional manner on the sensor part substrate 110. More specifically, the adhesive part 180 is formed in a wall shape on the sensor part substrate 110, having; a first wall portion 181 formed along a circumference on the sensor part substrate 110; and a second wall portion 182 formed between the laser diode 120 and the photodiode 160 on the sensor part substrate 110. The first wall portion 181 is formed to surround all the laser diode 120, the electrode 130, the wire line 140, the laser diode drive circuit 160, the photo diode 160, and the photodiode amplifier 170, viewed in a two-dimensional manner on the sensor part substrate 110. Thus, by virtue of the first wall portion 181, it is possible to prevent the light from the surroundings of the sensor part 100 from entering into the sensor part 100 (i.e. inner than the first wall portion 181 on the sensor part substrate 110). The second wall portion 182 is formed to connect a portion formed along one side of the sensor part substrate 110 of the first wall portion 181 and a portion formed along the other side opposed to the one side of the first wall portion 181, between the laser diode 120 and the photodiode 160 on the sensor part substrate 110. By virtue of the second wall portion 182, it is possible to shield between the laser diode 120 and the photodiode 160 from the light. Thus, for example, it is possible to block the light going to the photodiode 160 as it is, without being applied to the specimen, out of the light emitted from the laser diode 120. In other words, it is possible to prevent the light which does not have to be detected by the photodiode 160 from entering the photodiode 160 from the laser diode 120 side to the photodiode 160 side on the sensor part substrate 110, thereby increasing the detection accuracy.

The front plate 190 is disposed above the laser diode 120, the photodiode 160, and the like (in other words, at a predetermined interval from the sensor part substrate 110, on the front surface side of the sensor part substrate 110 where the laser diode 120 and the like are disposed). In other words, the front plate 190 is disposed to face the sensor part substrate 110 via the adhesive part 180.

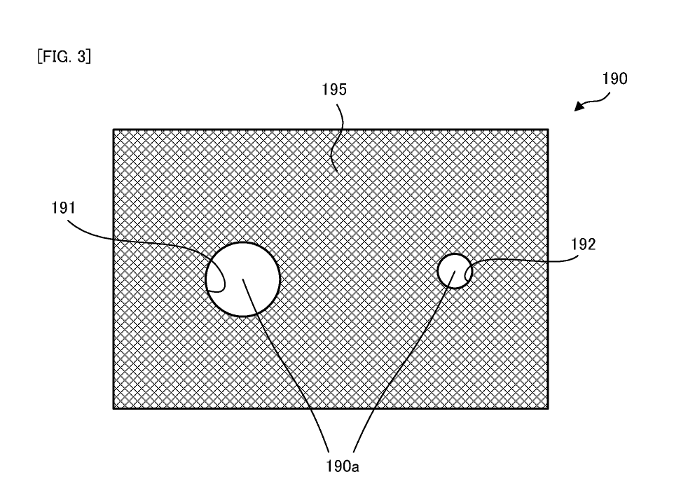

FIG. 3 is a plan view showing the structure of the front plate of the blood flow sensor device in the first embodiment.

As shown in FIG. 2 and FIG. 3, the font plate 190 is provided with a transparent substrate 190a and a light shielding film 195.

The transparent substrate 190a is a transparent substrate which can transmit the light from the laser diode 120 and the light from the specimen. As the transparent substrate 190a, for example, a resin substrate, a glass substrate, or the like can be used.

The light shielding film 195 is disposed each of two substrate surfaces of the transparent substrate 190a (i.e. the substrate surface opposed to the sensor part substrate 110, and the substrate surface opposite to the above substrate surface. The light shielding film 195 defines an exit aperture 191 for letting out or emitting the light from the laser diode 120 to the exterior, and an entrance aperture 192 for letting in the light reflected or scattered from the specimen. The light shielding film 195 limits the light entering the photodiode 160 and allows the incidence of only the light from directly above (i.e. in a top-to-bottom direction in FIG. 2). Thus, it is possible to prevent the light that does not have to be detected from entering the photodiode 160, thereby increasing the detection accuracy. Incidentally, the diameter of the entrance aperture 192 is, for example, about 40 μm.

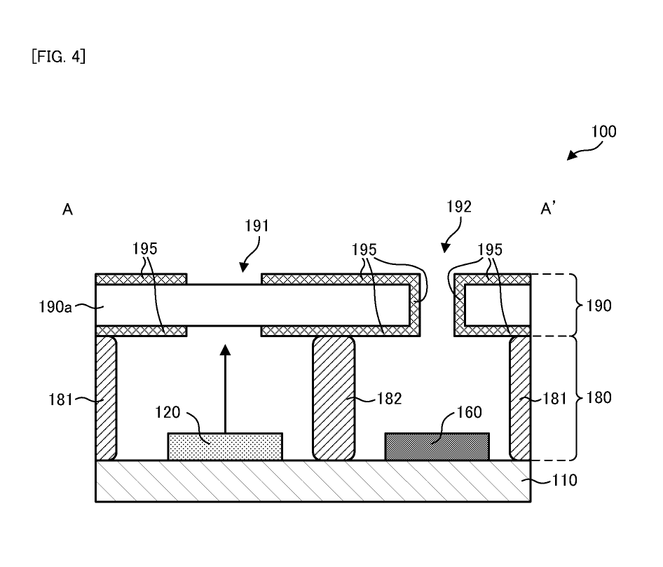

FIG. 4 is a cross sectional view having the same concept as in FIG. 2 in a first modified example.

As shown in FIG. 4, the entrance aperture 192 may be formed as a pinhole (or through hole) which penetrates through the transparent substrate 190a. The pinhole-shaped formation of the entrance aperture 192 allows the incidence of only the light from directly above (i.e. in a top-to-bottom direction in FIG. 2). In this case, by forming the light shielding film 195 on the inner wall of the entrance aperture 192 formed as the pinhole as well, it is possible to remove a path in which one portion of the light to be emitted from the exit aperture 191 can enter the photodiode 160 from the entrance aperture 192 via the inside of the front plate 190 (i.e. the transparent substrate 190a), thereby further increasing the detection accuracy.

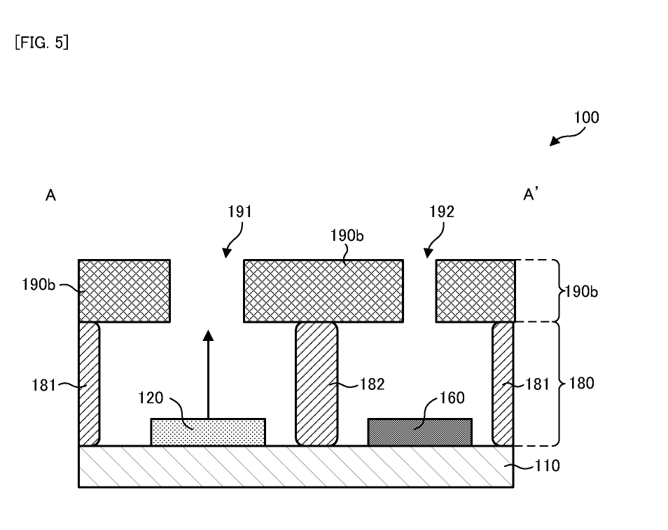

FIG. 5 is a cross sectional view having the same concept as in FIG. 2 in a second modified example.

As shown as the second modified example in FIG. 5, the sensor part 100 may be provided with a front plate 190a made of a light shielding material, instead of the front plate 190. In the front plate 190b, each of the exit aperture 191 and the entrance aperture 192 is formed as a pinhole which penetrates through the front plate 190b. In this case, it is not necessary to form the aforementioned light shielding film 195.

Incidentally, a protective plate made of a transparent substrate, such as a resin substrate and a glass substrate, may be disposed on the upper surface side of the front plate 190. In this case, the protective plate can increase the durability of the sensor part 100. Moreover, the same effect can be obtained by molding (or shaping) the entire front plate or the portion where the through hole is formed with resin which is transparent to the light from the laser diode 120, or by filling the through hole with the transparent resin or the like.

The sensor part substrate 110 is desirably a substrate made of a light shielding material; however, it may be formed of a material through which an infrared ray can be transmitter, such as Si (silicon), in order to unify an electronic circuit and a photodiode. In this case, a light shielding process may be performed separately by using a light shielding resist or the like.

Back in FIG. 1 and FIG. 2 again, particularly in the first embodiment, as described above, the sensor part substrate 110 on which the laser diode 120, the photodiode 160 and the like are formed and the front plate 190 are bonded to each other by the adhesive part 180. In other words, the sensor part 100 of the blood flow sensor device in the first embodiment has a laminated structure in which the sensor part substrate 110 on which the laser diode 120, the photodiode 160 and the like are formed and the front plate 190 are laminated via the adhesive part 180. Moreover, to put it another way, the sensor part 100 of the blood flow sensor device in the first embodiment has a relatively simple structure, which is a trilaminar structure, in which the sensor part substrate 110, the adhesive part 180, and the front plate 190 are laminated in this order. Thus, it is possible to simplify or reduce each process in a manufacturing process. Therefore, it is possible to increase a yield, thereby reducing manufacturing cost.

Next, the structure of the entire blood flow sensor device in the first embodiment will be explained with reference to FIG. 6.

FIG. 6 is a block diagram showing the structure of the blood flow sensor device in the first embodiment.

In FIG. 6, the blood flow sensor device in the first embodiment is provided with an A/D converter 310 and a blood flow velocity digital signal processor (DSP) 320, in addition to the aforementioned sensor part 100. Incidentally, in this embodiment, the laser diode drive circuit 150 and the photodiode amplifier 179 are formed on the sensor part substrate; however, they may be provided separately from the sensor part 100 without being formed on the sensor part substrate 110 as in the A/D converter 310 and the blood flow velocity DSP 320, or they may be unified on the sensor part substrate 110 including the A/D converter 310 and the blood flow velocity DSP 320. Alternatively, other substrates having their respective functions may be laminated with the sensor part substrate 110, and they may be mounted in an electrically connecting method or the like by wiring and through-hole interconnection. By bringing the A/D converter 310 and the blood flow velocity DSP 320 close to the sensor part substrate 110, a sufficient SN ratio (Signal to Noise Ratio) and a sufficient band can be ensured in weak or faint signal processing.

The A/D converter 310 converts the electric signal outputted from the photodiode amplifier 170, from an analog signal to a digital signal. In other words, the electric signal obtained by the photodiode 160 is amplified by the photodiode amplifier 170, and then it is converted to the digital signal by the A/D converter 310. The A/D converter 310 outputs the digital signal to the blood flow velocity DSP 320.

The blood flow velocity DSP 320 is one example of the “calculating part” of the present invention, and it calculates the blood flow velocity by performing a predetermined arithmetic process on the digital signal inputted from the A/D converter 310.

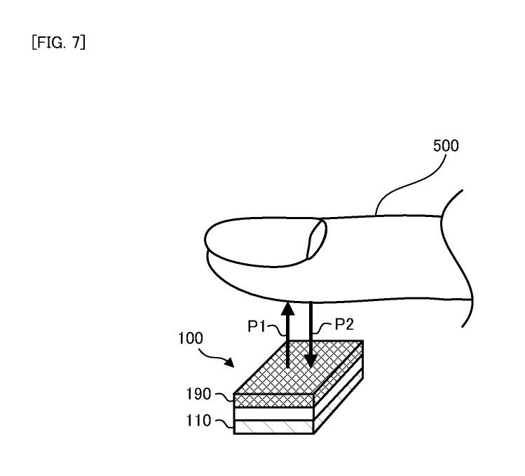

Next, the measurement of the blood flow velocity by the blood flow sensor device in the first embodiment will be explained with reference to FIG. 7 in addition to FIG. 6.

FIG. 7 is a conceptual view showing one example of how to use the blood flow sensor device in the first embodiment.

As shown in FIG. 7, the blood flow sensor device in the first embodiment measures the blood flow velocity by irradiating a fingertip 500, which is one example of the specimen, with laser light with a predetermined wavelength (e.g. shortwave light with a wavelength of 780 nm, or long-wave light with a wavelength of 830 nm) by using the laser diode 120. At this time, a portion irradiated with the laser light is more desirably a portion in which blood capillaries are distributed densely in a position relatively close to the epidermis (e.g. hand, leg, face, ear, or the like). Incidentally, in FIG. 7, an arrow P1 conceptually shows the light emitted from the sensor part 100. Moreover, in the measurement of the blood flow velocity, the blood flow sensor device in the first embodiment is typically used in the condition that the fingertip 500 touches the upper surface of the sensor part 100 (i.e. the upper surface of the front plate 190); however, for convenience of explanation, FIG. 7 shows a gap between the fingertip 500 and the sensor part 100. However, according to the blood flow sensor device in the first embodiment, it is possible to measure the blood flow velocity even if the fingertip 500 does not touch the upper surface of the sensor part 100.

In FIG. 7, the laser light applied to the fingertip 500 penetrates to depth according to its wavelength, and it is reflected or scattered by the body tissue of the fingertip 500, such as blood flowing in blood vessels like the blood capillaries or the like and skin cells which constitute the epidermis. In general, the light with a longer wavelength allows the measurement in a deeper portion. Incidentally, in FIG. 7, an arrow P2 conceptually shows the light entering the sensor part 100 after being reflected or scattered by the body tissue of the fingertip 500. Then, the Doppler shift occurs in the light reflected or scattered by red blood cells flowing in the blood vessels, and the wavelength of the light changes depending on the transfer rate of the red blood cells or the rate at which the blood flows (i.e. the blood flowing velocity). On the other hand, as for the light reflected or scattered by the skin cells or the like which can be considered immovable with respect to the red blood cells, the wavelength of the light does not change. By those lights interfering with each other, an optical beat signal corresponding to the Doppler shift amount is detected on the photodiode 160 (refer to FIG. 6). The blood flow velocity DSP 320 (refer to FIG. 6) performs frequency analysis on the optical beat signal detected by the photodiode 160 and calculates the Doppler shift amount, thereby calculating the blood flow velocity.

As explained in detail above, according to the blood flow sensor device in the first embodiment, it is provided with the adhesive part 180 made of the light shielding adhesive, so that it is possible to prevent the light which does not have to be detected by the photodiode 160 from entering the photodiode 160. Thus, the blood flow velocity in the specimen can be detected highly accurately. Moreover, according to the blood flow sensor device in the first embodiment, the sensor part 100 has a relatively simple structure, which is a trilaminar structure, in which the sensor part substrate 110, the adhesive part 180, and the front plate 190 are laminated in this order. Thus, it is possible to increase the yield and to reduce the manufacturing cost, and it is suitable for mass production.

### <Second Embodiment of Light-Emitting Sensor Device>

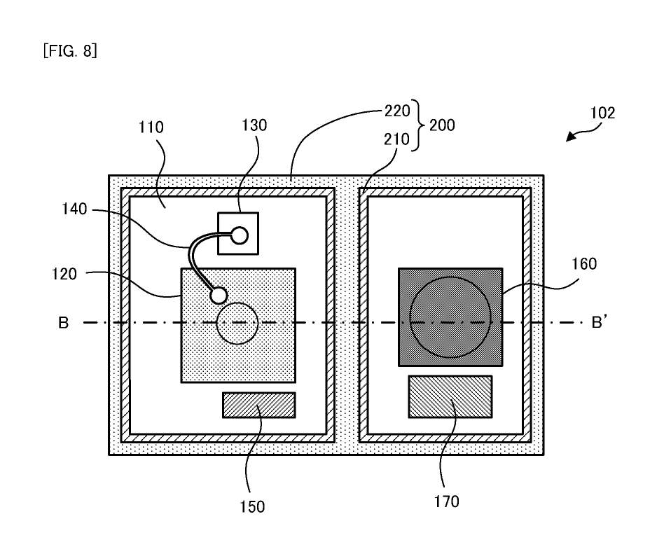

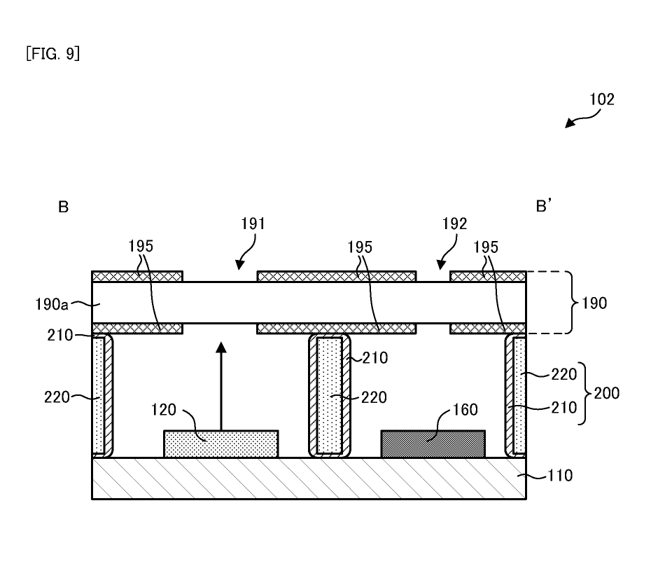

A blood flow sensor device in a second embodiment will be explained with reference to FIG. 8 and FIG. 9.

Firstly, the structure of a sensor part of the blood flow sensor device in the first embodiment will be explained with reference to FIG. 1 to FIG. 3. FIG. 8 is a plan view showing the structure of a sensor part of the blood flow sensor device in the second embodiment. FIG. 9 is a B-B′ cross sectional view in FIG. 8. Incidentally, in FIG. 8, for convenience of explanation, the illustration of the front plate 190 shown in FIG. 9 is omitted, and it shows a cross sectional view of an adhesive part 200 in a case where the adhesive part 200 is cut so as to include a frame member 220 on a plane along the substrate surface of the sensor part substrate 110. Incidentally, in FIG. 8 and FIG. 9, the same constituents as those in the first embodiment shown in FIG. 1 to FIG. 7 will carry the same reference numerals, and the explanation thereof will be omitted, as occasion demands.

The blood flow sensor apparatus in the second embodiment is different from the blood flow sensor apparatus in the first embodiment described above in the point that it is provided with a sensor part 102 instead of the sensor part 100 in the first embodiment described above, and it is constructed in substantially the same manner as the blood flow sensor apparatus in the first embodiment described above in other points.

In FIG. 8 and FIG. 9, the sensor part 102 of the blood flow sensor apparatus in the second embodiment is different from the sensor part 100 of the blood flow sensor apparatus in the first embodiment described above in the point that it is provided with the adhesive part 200 instead of the adhesive part 180 in the first embodiment described above, and it is constructed in substantially the same manner as the sensor part 100 of the blood flow sensor apparatus in the first embodiment described above in other points.

As shown in FIG. 8 and FIG. 9, the adhesive part 200 is made of an adhesive portion 210 and a frame member 220. The adhesive part 200 is formed to surround each of the laser diode 120 and the photo diode 160, viewed in a two-dimensional manner on the sensor part substrate 110.

The adhesive portion 210 is made of a light shielding adhesive, and it is formed to cover the upper surface of the frame member 220 (i.e. a surface of the frame member 220 opposed to the front plate 190), the lower surface (i.e. a surface of the frame member 220 opposed to the sensor part substrate 110) and one portion of the side surfaces (more specifically, a side surface opposed to the laser diode 120 and a side surface opposed to the photodiode 160, in the frame member 220). The light shielding adhesive may be an acrylic, epoxy, polyimide or silicon type adhesive in which conducting particles, such as carbon black, aluminum and silver, are dispersed inside, or an acrylic, epoxy, polyimide or silicon type adhesive in which pigments, such as black pigments, are dispersed inside.

The frame member 220 is, for example, made of resin or the like, having higher strength than the adhesive portion 210, and it is formed to surround each of the laser diode 120 and the photo diode 160, viewed in a two-dimensional manner on the sensor part substrate 110. The frame member 220 may be formed of, for example, silicon, metal, ceramics, or the like, having higher strength than the adhesive portion 210.

As described above, particularly in the second embodiment, the adhesive part 200 is made of the adhesive portion 210 and the frame member 220, so that it is possible to increase the strength of the adhesive part 200 in comparison with a case where the adhesive part 200 does not have the frame member 220 (i.e. the adhesive part 200 is made only of the adhesive). Thus, a change in gap between the sensor part substrate 110 and the front plate 190 can be limited or controlled. Therefore, it is possible to prevent a reduction in detection accuracy.

Incidentally, according to the second embodiment, one portion of the adhesive portion 210 covers the side surface opposed to the laser diode 120 and the side surface opposed to the photodiode 160 in the frame member 220, so that the frame member 220 can be formed of a transparent material. The frame member 220 may be formed of a material having a light shielding property.

### <Third Embodiment of Light-Emitting Sensor Device>

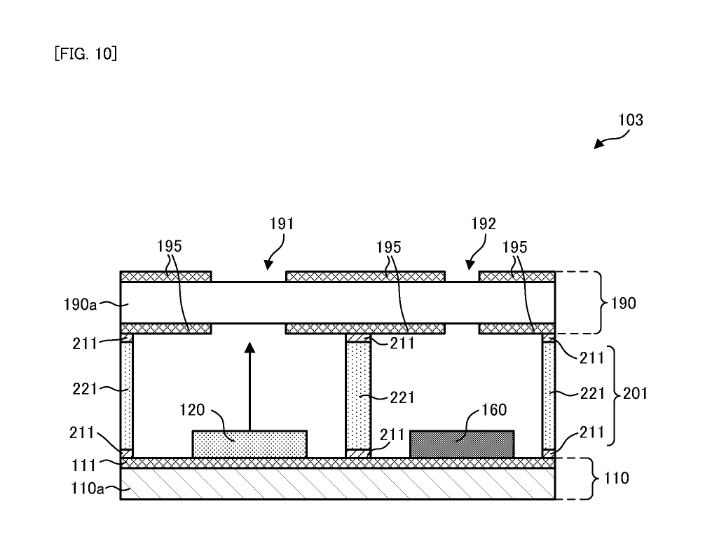

A blood flow sensor device in a third embodiment will be explained with reference to FIG. 10.

FIG. 10 is a cross sectional view having the same concept as in FIG. 2 in the third embodiment. Incidentally, in FIG. 10, the same constituents as those in the first embodiment shown in FIG. 1 to FIG. 7 will carry the same reference numerals, and the explanation thereof will be omitted, as occasion demands.

The blood flow sensor apparatus in the third embodiment is different from the blood flow sensor apparatus in the first embodiment described above in the point that it is provided with a sensor part 103 instead of the sensor part 100 in the first embodiment described above, and it is constructed in substantially the same manner as the blood flow sensor apparatus in the first embodiment described above in other points.

In FIG. 10, the sensor part 103 of the blood flow sensor apparatus in the second embodiment is different from the sensor part 100 of the blood flow sensor apparatus in the first embodiment described above in the point that it is provided with an adhesive part 201 instead of the adhesive part 180 in the first embodiment described above, and it is constructed in substantially the same manner as the sensor part 100 of the blood flow sensor apparatus in the first embodiment described above in other points.

As shown in FIG. 10, the adhesive part 201 is made of an adhesive portion 211 and a frame member 221.

The frame member 221 is formed substantially as in the frame member 220 in the second embodiment described above with reference to FIG. 8 and FIG. 9. In other words, the frame member 221 is made of resin or the like, having higher strength than the adhesive portion 211 and having a light shielding property, and it is formed to surround each of the laser diode 120 and the photo diode 160, viewed in a two-dimensional manner on the sensor part substrate 110. The frame member 221 may be formed of, for example, silicon, metal, ceramics, or the like.

The adhesive portion 211 is made of a light shielding adhesive, and it is formed to cover the upper surface of the frame member 221 (i.e. a surface of the frame member 221 opposed to the front plate 190) and the lower surface (i.e. a surface of the frame member 221 opposed to the sensor part substrate 110) but not formed on the side surfaces of the frame member 221. The light shielding adhesive may be an acrylic, epoxy, polyimide or silicon type adhesive in which conducting particles, such as carbon black, aluminum and silver, are dispersed inside, or an acrylic, epoxy, polyimide or silicon type adhesive in which pigments, such as black pigments, are dispersed inside.

As described above, particularly in the third embodiment, the adhesive part 201 is made of the adhesive portion 211 and the frame member 221, so that it is possible to increase the strength of the adhesive part 201 in comparison with a case where the adhesive part 201 does not have the frame member 221 (i.e. the adhesive part 201 is made only of the light shielding adhesive). Thus, a change in gap between the sensor part substrate 110 and the front plate 190 can be limited or controlled.

Incidentally, according to the third embodiment, the adhesive part 201 is provided with the frame member 221 having a light shielding property and the adhesive portion 211 made of the light shielding adhesive, so that it is possible to prevent the light detected by the photodiode 160 from changing due to unnecessary light from the surroundings of the sensor part 103 and light directly going from the laser diode 120 to the photodiode 160.

### <First Embodiment of Method of Manufacturing Light-Emitting Sensor Device>

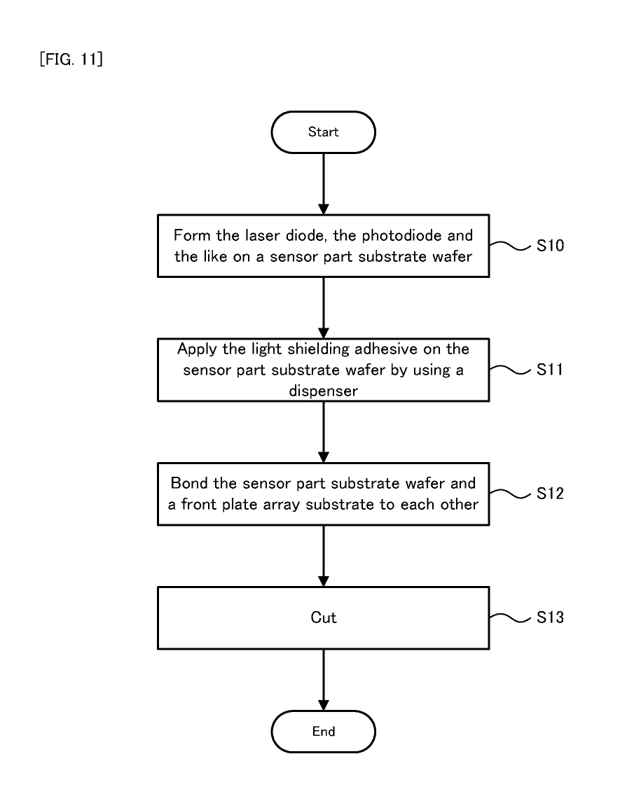

A method of manufacturing the light-emitting sensor device in a first embodiment will be explained with reference to FIG. 11 to FIG. 13. Incidentally, the method of manufacturing the light-emitting sensor device in the first embodiment is one example of the first method of manufacturing the light-emitting sensor device of the present invention, and it is possible to manufacture the blood flow sensor device in the first embodiment described above. Hereinafter, a detailed explanation will be given on a method of manufacturing the sensor part 100 of the blood flow sensor device in the first embodiment described above.

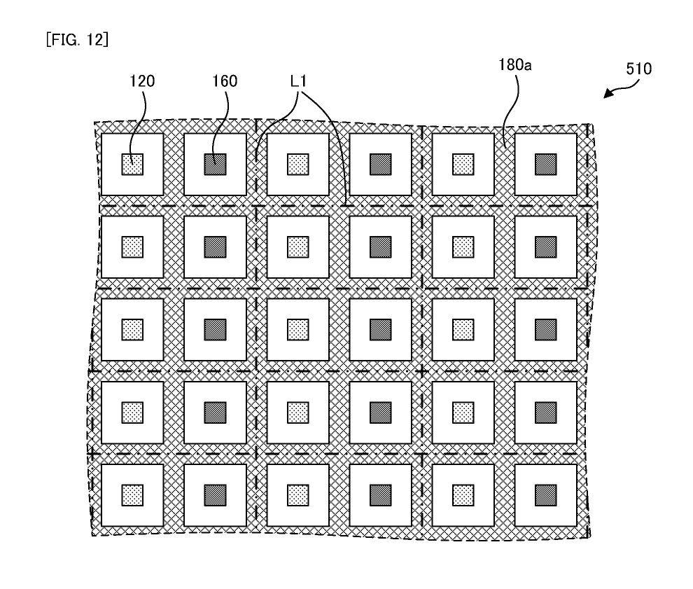

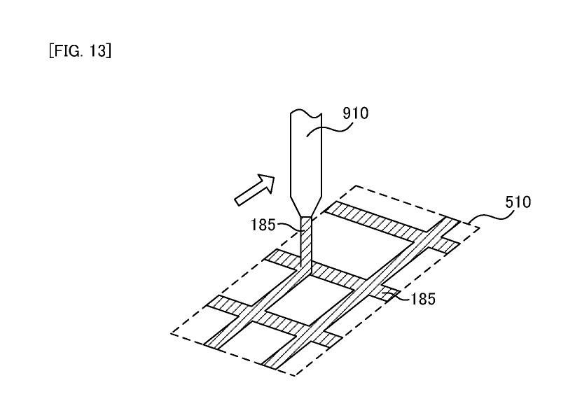

FIG. 11 is a flowchart showing a flow of the method of manufacturing the light-emitting sensor device in the first embodiment. FIG. 12 is a plan view showing a sensor part substrate wafer after the laser diode, the photodiode and the like are formed. FIG. 13 is a conceptual view showing a process of applying the adhesive in the method of manufacturing the light-emitting sensor device in the first embodiment.

In FIG. 11 and FIG. 12, firstly, the laser diode 120, the photodiode 160 and the like are formed on a sensor part substrate wafer 510 (step S10). The sensor part substrate wafer 510 is one example of the “first large substrate” of the present invention, and it is a semiconductor wafer including a plurality of sensor part substrates 110 (refer to FIG. 1 and FIG. 2). More specifically, after the laser diode drive circuit 150, the photodiode 160, the photodiode amplifier 170, and the electrode 130 are formed on the sensor part substrate wafer 510 by using a semiconductor process technology, the laser diode 120 is mounted.

Then, the light shielding adhesive is applied on the sensor part substrate wafer 510 by using a dispenser (step S11). In other words, as shown in FIG. 12 and FIG. 13, a light shielding adhesive 185 is applied to an adhesive area 180a on the sensor part substrate wafer 510 by using a dispenser 910. The adhesive area 180a is defined in a grid shape which surrounds each of the laser diode 120 and the photodiode 160 on the sensor part substrate wafer 510. As the light shielding adhesive 185, for example, thermosetting resin is used in which conducting particles, such as carbon black, aluminum and silver, are dispersed inside. The light shielding adhesive 185 may be thermosetting resin in which pigments, such as black pigments, are dispersed inside. After the light shielding adhesive 185 is applied onto the sensor part substrate wafer 510, the applied light shielding adhesive 185 is temporarily hardened by heating it for a predetermined time. Incidentally, as the light shielding adhesive, a pressure-sensitive adhesive having a light shielding property may be used.

Then, the sensor part substrate wafer 510 and a front plate array substrate are bonded to each other (step S12). The front plate array substrate (not illustrated) is one example of the “second large substrate” of the present invention, and it is a substrate including a plurality of front plates 190 (refer to FIG. 2 and FIG. 3) (e.g. a substrate in which the plurality of front plates 190 are arranged in a matrix shape). A process of forming such a front plate array substrate may be performed in advance, such as being performed in parallel with the process of forming the laser diode and the like on the sensor part substrate wafer 510 (the step S10). Incidentally, in the process of forming the front plate array substrate, the light shielding film 195 (refer to FIG. 2 and FIG. 3) is formed in a predetermined pattern in a transparent substrate wafer including a plurality of transparent substrates 190a (refer to FIG. 2 and FIG. 3).

Specifically, the sensor part substrate wafer 510 to which the light shielding adhesive 185 is applied and the front plate array substrate are disposed to face each other and are positioned. Then, the light shielding adhesive 185 is pressured by bringing the sensor part substrate wafer 510 and the front plate array substrate close to each other at a predetermined distance. Then, the light shielding adhesive 185 is hardened by heating, by which the sensor part substrate wafer 510 and the front plate array substrate are bonded to each other by the light shielding adhesive 185.

Then, the sensor part substrate wafer 510, the front plate array substrate, and the light shielding adhesive 185 are cut along a section line L1 (step S13). The section line L1 is defined along the circumference of each of the plurality of sensor part substrates 110 on the sensor part substrate wafer 510. The sensor part substrate wafer 510, the front plate array substrate, and the light shielding adhesive 185 are cut along the section line L1, for example, by dicing or die cutting. By this, a plurality of sensor parts 100 can be manufactured simultaneously.

As explained above, according to the method of manufacturing the light-emitting sensor device in the first embodiment, it is possible to manufacture the sensor part 100 of the blood flow sensor device in the first embodiment described above. Here, particularly in this embodiment, the light shielding adhesive 185 is applied by the dispenser 910 so as to surround each of the laser diode 120 and the photodiode 160 on the sensor part substrate wafer 510, which facilitates the formation of the adhesive part 180 (refer to FIG. 1 and FIG. 2) made only of the light shielding adhesive 185. Moreover, after the sensor part substrate wafer 510 and the front plate array substrate are bonded to each other by the light shielding adhesive 185, the sensor part substrate wafer 510 and the front plate array substrate are cut along the section line L1, which allows a plurality of sensor parts 100 to be manufactured simultaneously.

### <Second Embodiment of Method of Manufacturing Light-Emitting Sensor Device>

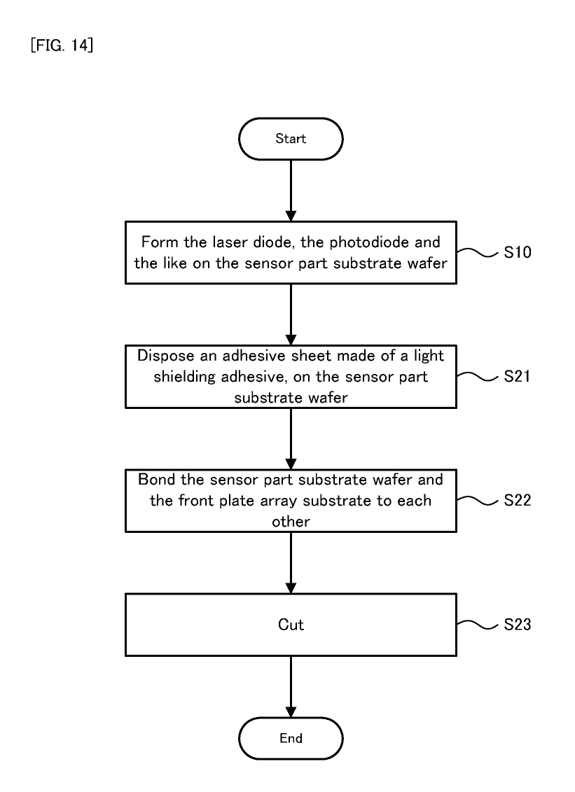

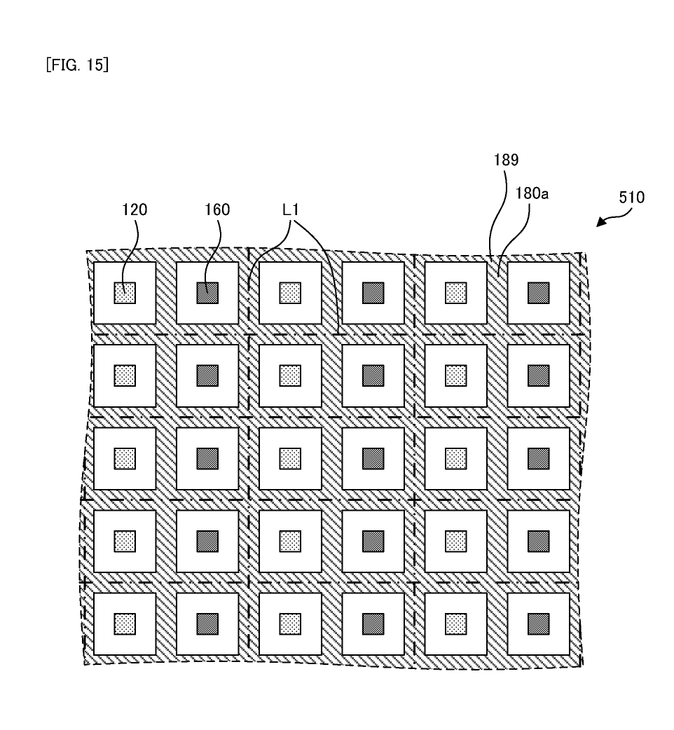

A method of manufacturing the light-emitting sensor device in a second embodiment will be explained with reference to FIG. 14 and FIG. 15. Incidentally, the method of manufacturing the light-emitting sensor device in the second embodiment is one example of the second method of manufacturing the light-emitting sensor device of the present invention, and it is possible to manufacture the blood flow sensor device in the first embodiment described above. Hereinafter, a detailed explanation will be given on a method of manufacturing the sensor part 100 of the blood flow sensor device in the first embodiment described above.

FIG. 14 is a flowchart showing a flow of the method of manufacturing the light-emitting sensor device in the second embodiment. FIG. 15 is a conceptual view showing a process of setting an adhesive seal in the method of manufacturing the light-emitting sensor device in the second embodiment. Incidentally, in FIG. 14 and FIG. 15, the same manufacturing processes and constituents as those in the method of manufacturing the light-emitting sensor device in the first embodiment shown in FIG. 11 to FIG. 13 will carry the same reference numerals, and the explanation thereof will be omitted, as occasion demands.

In FIG. 14 and FIG. 15, firstly, the laser diode 120, the photodiode 160 and the like are formed on the sensor part substrate wafer 510 (the step S10).

Then, an adhesive sheet 189 made of a light shielding adhesive is disposed on the sensor part substrate wafer 510 (step S21). In other words, as shown in FIG. 15, an adhesive sheet 189 in a grid shape, which can surround each of the laser diode 120 and the photodiode 160, is disposed such that it overlaps the adhesive area 180a. The adhesive sheet 189 is a thermosetting or pressure-sensitive adhesive sheet. In the adhesive sheet 189, pigments, such as black pigments, are dispersed inside, and the adhesive sheet 189 has a light shielding property.

Then, the sensor part substrate wafer 510 and the front plate array substrate are bonded to each other (step S22). More specifically, the sensor part substrate wafer 510 in which the adhesive sheet 189 is disposed and the front plate array substrate are disposed to face each other and are positioned. Then, if the adhesive sheet 189 is a pressure-sensitive adhesive sheet, the adhesive sheet 189 is pressured by bringing the sensor part substrate wafer 510 and the front plate array substrate close to each other at a predetermined distance, by which the sensor part substrate wafer 510 and the front plate array substrate are bonded to each other by the adhesive sheet 189. Alternatively, if the adhesive sheet 189 is a thermosetting adhesive sheet, the adhesive sheet 189 is hardened by heating, by which the sensor part substrate wafer 510 and the front plate array substrate are bonded to each other by the adhesive sheet 189.

Then, the sensor part substrate wafer 510, the front plate array substrate, and the adhesive sheet 189 are cut along the section line L1 (step S23). In other words, the sensor part substrate wafer 510, the front plate array substrate, and the adhesive sheet 189 are cut along the section line L1, for example, by dicing or die cutting. By this, a plurality of sensor parts 100 can be manufactured simultaneously.

As explained above, according to the method of manufacturing the light-emitting sensor device in the second embodiment, it is possible to manufacture the sensor part 100 of the blood flow sensor device in the first embodiment described above. Here, particularly in this embodiment, the sensor part substrate wafer 510 and the front plate array substrate are bonded to each other by the adhesive sheet 189, which is formed to surround each of the laser diode 120 and the photodiode 160 on the sensor part substrate wafer 510 and which is made of the light shielding adhesive, which facilitates the formation of the adhesive part 180 made only of the light shielding adhesive. Moreover, after the sensor part substrate wafer 510 and the front plate array substrate are bonded to each other by the adhesive sheet 189, the sensor part substrate wafer 510 and the front plate array substrate are cut along the section line L1, which allows a plurality of sensor parts 100 to be manufactured simultaneously.

### <Third Embodiment of Method of Manufacturing Light-Emitting Sensor Device>

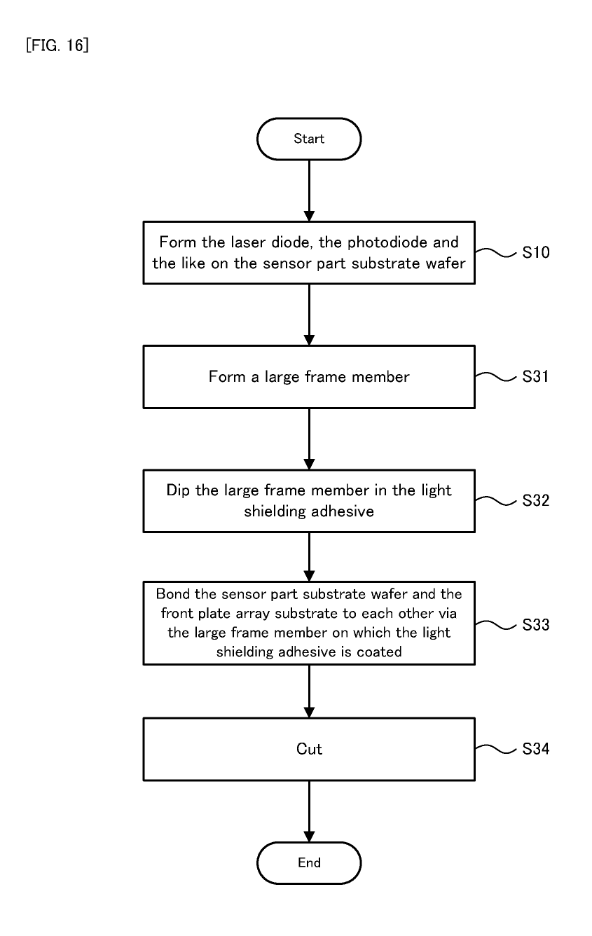

A method of manufacturing the light-emitting sensor device in a third embodiment will be explained with reference to FIG. 16 to FIG. 18. Incidentally, the method of manufacturing the light-emitting sensor device in the third embodiment is one example of the third method of manufacturing the light-emitting sensor device of the present invention, and it is possible to manufacture the blood flow sensor device in the second embodiment described above. Hereinafter, a detailed explanation will be given on a method of manufacturing the sensor part 102 of the blood flow sensor device in the second embodiment described above with reference to FIG. 8 and FIG. 9.

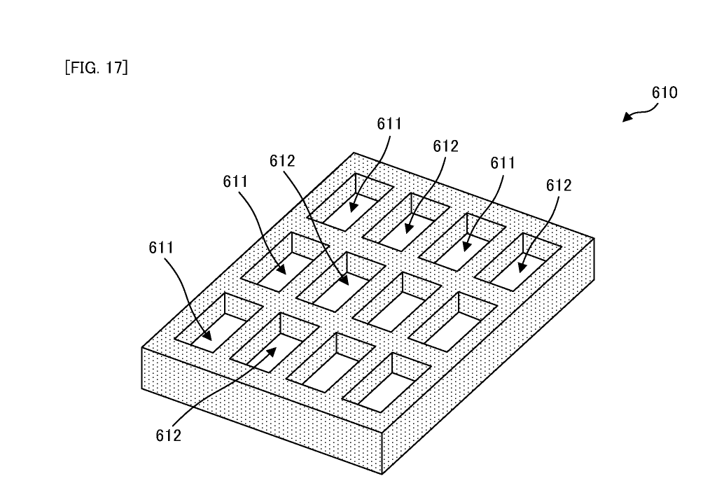

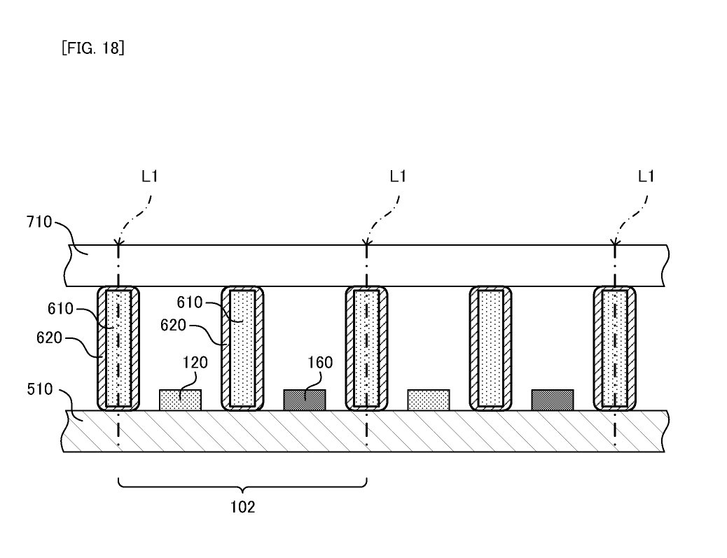

FIG. 16 is a flowchart showing a flow of the method of manufacturing the light-emitting sensor device in the third embodiment. FIG. 17 is a perspective view showing a large frame member in the method of manufacturing the light-emitting sensor device in the third embodiment. FIG. 18 is a cross sectional view showing that the sensor part substrate wafer and the front plate array substrate are disposed to face each other via the large frame member after a light shielding adhesive is applied by dipping, in the method of manufacturing the light-emitting sensor device in the third embodiment. Incidentally, in FIG. 16 to FIG. 18, the same manufacturing processes and constituents as those in the method of manufacturing the light-emitting sensor device in the first embodiment shown in FIG. 11 to FIG. 13 will carry the same reference numerals, and the explanation thereof will be omitted, as occasion demands. Moreover, for convenience of explanation, FIG. 17 shows only one portion of the large frame member, but another portion is constructed in the same manner.

In FIG. 16 and FIG. 17, firstly, the laser diode 120, the photodiode 160 and the like are formed on the sensor part substrate wafer 510 (the step S10).

Then, a large frame member is formed (step S31). In other words, a large frame member 610 as shown in FIG. 16 is formed. More specifically, the large frame member 610 is formed in a grid shape which can surround each of the laser diode 120 and the photodiode 160 on the sensor part substrate wafer 510. In other words, the large frame member 610 is formed in a plate shape having; a plurality of openings 611 each of which corresponds to respective one of a plurality of laser diodes 120 formed on the sensor part substrate wafer 510; and a plurality of openings each of which corresponds to respective one of a plurality of photodiodes 160 formed on the sensor part substrate wafer 510. The large frame member 610 is formed, for example, by a resin molding technique, an etching technique, or the like. Incidentally, the process of forming the large frame member 610 (the step S31) may be performed in advance, such as being performed in parallel with the process of forming the laser diode 120 and the like on the sensor part substrate wafer 510 (the step S10).

Then, the large frame member 610 is dipped in the light shielding adhesive (step S32). In other words, by immersing or dipping the large frame member 610 in the light shielding adhesive, the light shielding adhesive is applied on the entire surface of the large frame member 610. By this, the entire surface of the large frame member 610 is covered (i.e. coated) with the light shielding adhesive.

Then, the sensor part substrate wafer 510 and the front plate array substrate are bonded to each other via the large frame member 610 coated with the light receiving adhesive (step S33). More specifically, as shown in FIG. 18, the sensor part substrate wafer 510 and the front plate array substrate are disposed to face each other via the large frame member 610 coated with the light shielding adhesive 620, and are positioned. Then, the light blocking adhesive 620 is hardened by heating, by which the sensor part substrate wafer 510 and the front plate array substrate are bonded to each other by the light blocking adhesive 620.

Then, the sensor part substrate wafer 510, the front plate array substrate 710, the large frame member 610, and the light shielding adhesive 620 are cut along the section line L1, for example, by dicing or die cutting (step S34). By this, a plurality of sensor parts 102 can be manufactured simultaneously.

As explained above, according to the method of manufacturing the light-emitting sensor device in the third embodiment, it is possible to manufacture the sensor part 102 of the blood flow sensor device in the second embodiment described above with reference to FIG. 9 and FIG. 10. Here, particularly in this embodiment, the light shielding adhesive 620 is applied to the large frame member 610 by dipping, which facilitates the formation of the adhesive part 200 (refer to FIG. 9) made of the adhesive portion 210 and the frame member 220. Moreover, after the sensor part substrate wafer 510 and the front plate array substrate 710 are bonded to each other by the light shielding adhesive 620, the sensor part substrate wafer 510, the front plate array substrate 710, and the large frame member 610 are cut along the section line L1, which allows a plurality of sensor parts 102 to be manufactured simultaneously.

### <Fourth Embodiment of Method of Manufacturing Light-Emitting Sensor Device>

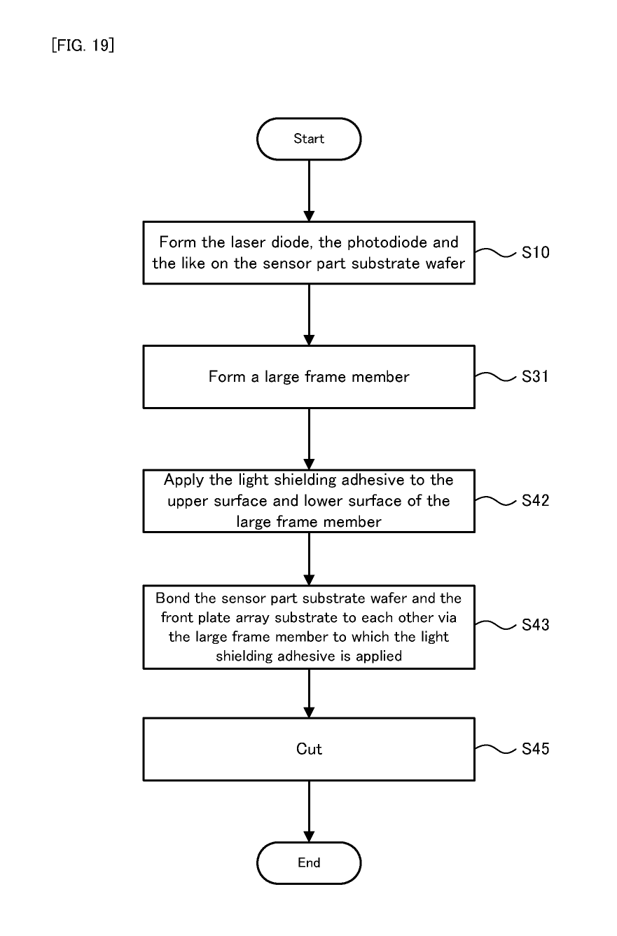

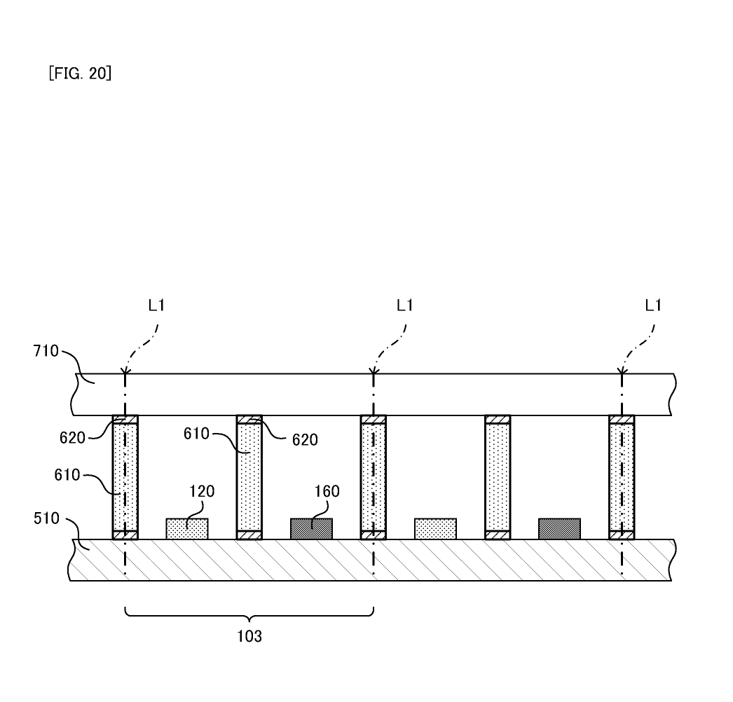

A method of manufacturing the light-emitting sensor device in a fourth embodiment will be explained with reference to FIG. 19 and FIG. 20. Incidentally, the method of manufacturing the light-emitting sensor device in the fourth embodiment is one example of the fourth method of manufacturing the light-emitting sensor device of the present invention, and it is possible to manufacture the blood flow sensor device in the third embodiment described above. Hereinafter, a detailed explanation will be given on a method of manufacturing the sensor part 103 of the blood flow sensor device in the third embodiment described above with reference to FIG. 10.

FIG. 19 is a flowchart showing a flow of the method of manufacturing the light-emitting sensor device in the fourth embodiment. FIG. 20 is a cross sectional view showing that the sensor part substrate wafer and the front plate array substrate are disposed to face each other via the large frame member to which the light shielding adhesive is applied, in the method of manufacturing the light-emitting sensor device in the fourth embodiment. Incidentally, in FIG. 19 and FIG. 20, the same manufacturing processes and constituents as those in the method of manufacturing the light-emitting sensor device in the third embodiment shown in FIG. 16 to FIG. 8 will carry the same reference numerals, and the explanation thereof will be omitted, as occasion demands.

In FIG. 19, firstly, the laser diode 120, the photodiode 160 and the like are formed on the sensor part substrate wafer 510 (the step S10).

Then, the large frame member is formed (the step S31). In other words, as in the method of manufacturing the light-emitting sensor device in the third embodiment described above, the large frame member 610 as shown in FIG. 16 is formed.

Then, the light shielding adhesive is applied to the upper surface and lower surface of the large frame member 610 (step S42). In other words, in FIG. 16 and FIG. 20, for example, the light shielding adhesive of a thermosetting type is applied to the upper surface of the large frame member 610 (i.e. the surface opposed to the front plate array substrate 710) and the lower surface (i.e. the surface opposed to the sensor part substrate wafer 510) by using a roller or the like.

Then, the sensor part substrate wafer 510 and the front plate array substrate 710 are bonded to each other via the large frame member 610 to which the light receiving adhesive 620 is applied (step S43). More specifically, as shown in FIG. 20, the sensor part substrate wafer 510 and the front plate array substrate 710 are disposed to face each other via the large frame member 610 in which the light shielding adhesive 620 is applied to the upper surface and lower surface thereof, and are positioned. Then, the light blocking adhesive 620 is hardened by heating, by which the sensor part substrate wafer 510 and the front plate array substrate 710 are bonded to each other via the large frame member 610 (i.e. the sensor part substrate wafer 510 and the large frame member 610 are bonded to each other by a portion of the light shielding adhesive 620 applied to the lower surface of the large frame member 610, and the front plate array substrate 710 and the large frame member 610 are bonded to each other by a portion of the light shielding adhesive 620 applied to the upper surface of the large frame member 610).

Then, the sensor part substrate wafer 510, the front plate array substrate 710, the large frame member 610, and the light shielding adhesive 620 are cut along the section line L1, for example, by dicing or die cutting (the step S34). By this, a plurality of sensor parts 103 (refer to FIG. 10 as well) can be manufactured simultaneously.

As explained above, according to the method of manufacturing the light-emitting sensor device in the fourth embodiment, it is possible to manufacture the sensor part 103 of the blood flow sensor device in the second embodiment described above with reference to FIG. 10. Here, particularly in this embodiment, the light shielding adhesive 620 is applied to the upper surface and lower surface of the large frame member 610 by using a roller or the like, which facilitates the formation of the adhesive part 201 (refer to FIG. 10) made of the adhesive portion 211 and the frame member 221. Moreover, after the sensor part substrate wafer 510 and the front plate array substrate 710 are bonded to each other by the light shielding adhesive 620, the sensor part substrate wafer 510, the front plate array substrate 710, and the large frame member 610 are cut along the section line L1, which allows a plurality of sensor parts 103 to be manufactured simultaneously.

The present invention is not limited to the aforementioned example, but various changes may be made, if desired, without departing from the essence or spirit of the invention which can be read from the claims and the entire specification. A light-emitting sensor device and a method of manufacturing the same, which involve such changes, are also intended to be within the technical scope of the present invention.

### INDUSTRIAL APPLICABILITY

The light-emitting sensor device and the method of manufacturing the same of the present invention can be applied to a blood flow sensor device or the like capable of measuring a blood flow velocity or the like.

1. A light-emitting sensor device comprising:
a substrate;
an irradiating part, disposed on said substrate, for applying light to a specimen;
a light receiving part, disposed on said substrate, for detecting light from the specimen caused by the applied light;
a front plate disposed to face said substrate, on a front surface side of said substrate in which said irradiating part is disposed; and
an adhesive part which is formed to surround each of said irradiating part and said light receiving part viewed in a two-dimensional manner on said substrate, which includes a light shielding adhesive, and which bonds said substrate and said front plate to each other.

2. The light-emitting sensor device according to claim 1, wherein said adhesive part is made only of the light shielding adhesive.

3. The light-emitting sensor device according to claim 1, wherein said adhesive part includes a frame member which has higher strength than the light shielding adhesive and which surrounds each of said irradiating part and said light receiving part viewed in a two-dimensional manner on said substrate.

4. The light-emitting sensor device according to claim 1, wherein the light shielding adhesive is an acrylic, epoxy, polyimide or silicon type adhesive in which light shielding particles are dispersed inside.

5. The light-emitting sensor device according to claim 1, wherein said irradiating part and said light receiving part are integrated on said substrate.

6. The light-emitting sensor device according to claim 1, further comprising a calculating part for calculating a blood flow velocity associated with the specimen, on the basis of the detected light.

7. The light-emitting sensor device according to claim 1, wherein said irradiating part has a semiconductor laser for generating laser light as the light.

8. A method of manufacturing a light-emitting sensor device comprising: a substrate; an irradiating part, disposed on said substrate, for applying light to a specimen; a light receiving part, disposed on said substrate, for detecting light from the specimen caused by the applied light; a front plate disposed to face said substrate, on a front surface side of said substrate in which said irradiating part is disposed; and an adhesive part which is formed to surround each of said irradiating part and said light receiving part viewed in a two-dimensional manner on said substrate, which includes a light shielding adhesive, and which bonds said substrate and said front plate to each other, said method comprising:
a forming process of forming said irradiating part and said light receiving part on a first large substrate including a plurality of substrates;
an applying process of applying the light shielding adhesive so as to surround each of said irradiating part and said light receiving part on the first large substrate;
an adhering process of disposing a second large substrate including a plurality of front plates so as to face the first large substrate to which the light shielding adhesive is applied and of bonding the first and second large substrates to each other by the light shielding adhesive; and
a cutting process of cutting the first and second large substrates bonded to each other, along circumference of said substrate.

9. A method of manufacturing a light-emitting sensor device comprising: a substrate; an irradiating part, disposed on said substrate, for applying light to a specimen; a light receiving part, disposed on said substrate, for detecting light from the specimen caused by the applied light; a front plate disposed to face said substrate, on a front surface side of said substrate in which said irradiating part is disposed; and an adhesive part which is formed to surround each of said irradiating part and said light receiving part viewed in a two-dimensional manner on said substrate, which includes a light shielding adhesive, and which bonds said substrate and said front plate to each other, said method comprising:
a forming process of forming said irradiating part and said light receiving part on a first large substrate including a plurality of substrates;
a disposing process of disposing an adhesive sheet on the first large substrate, the adhesive sheet being formed to surround each of said irradiating part and said light receiving part on the first large substrate, the adhesive sheet being made of the light shielding adhesive;
an adhering process of disposing a second large substrate including a plurality of front plates so as to face the first large substrate on which the adhesive sheet is disposed and of bonding the first and second large substrates to each other by the adhesive sheet; and
a cutting process of cutting the first and second large substrates bonded to each other, along circumference of said substrate.

10. A method of manufacturing a light-emitting sensor device comprising: a substrate; an irradiating part, disposed on said substrate, for applying light to a specimen; a light receiving part, disposed on said substrate, for detecting light from the specimen caused by the applied light; a front plate disposed to face said substrate, on a front surface side of said substrate in which said irradiating part is disposed; and an adhesive part which is formed to surround each of said irradiating part and said light receiving part viewed in a two-dimensional manner on said substrate, which includes a light shielding adhesive, and which bonds said substrate and said front plate to each other, said method comprising:
a forming process of forming said irradiating part and said light receiving part on a first large substrate including a plurality of substrates;
an applying process of applying the light shielding adhesive to a large frame member by dipping, the large frame member having higher strength than the light shielding adhesive, the large frame member being formed to surround each of said irradiating part and said light receiving part viewed in a two-dimensional manner on the first large substrate;
an adhering process of disposing a second large substrate including a plurality of front plates so as to face the first large substrate via the large frame member to which the light shielding adhesive is applied and of bonding the first and second large substrates to each other by the light shielding adhesive; and
a cutting process of cutting the first and second large substrates bonded to each other, along circumference of said substrate.

11. A method of manufacturing a light-emitting sensor device comprising: a substrate; an irradiating part, disposed on said substrate, for applying light to a specimen; a light receiving part, disposed on said substrate, for detecting light from the specimen caused by the applied light; a front plate disposed to face said substrate, on a front surface side of said substrate in which said irradiating part is disposed; and an adhesive part which is formed to surround each of said irradiating part and said light receiving part viewed in a two-dimensional manner on said substrate, which includes a light shielding adhesive, and which bonds said substrate and said front plate to each other, said method comprising:
a forming process of forming said irradiating part and said light receiving part on a first large substrate including a plurality of substrates;
an applying process of applying the light shielding adhesive to a first surface opposed to the first large substrate and a second surface opposite to the first surface, in a large frame member which has higher strength than the light shielding adhesive and which is formed to surround each of said irradiating part and said light receiving part viewed in a two-dimensional manner on the first large substrate;
an adhering process of disposing a second large substrate including a plurality of front plates so as to face the first large substrate via the large frame member to which the light shielding adhesive is applied and of bonding the first and second large substrates to each other by the light shielding adhesive via the large frame member; and
a cutting process of cutting the first and second large substrates bonded to each other, along circumference of said substrate.
